(19) United States
(12) Patent Application Publication
(10) Pub. No.: US 2020/0403068 A1
(43) Pub. Date: Dec. 24, 2020

(54) A METHOD OF MAKING A GRAPHENE TRANSISTOR AND DEVICES

(71) Applicant: Paragraf Limited, Bomersham (GB)

(72) Inventors: Simon Thomas, Somersham (GB); Ivor Guiney, Somersham (GB)

(73) Assignee: Paragraf Limited, Somersham (GB)

(21) Appl. No.: 16/961,089

(22) PCT Filed: Jan. 10, 2019
(86) PCT No.: PCT/GB2019/050061

§ 371 Date: Jul. 9, 2020

(30) Foreign Application Priority Data
Jan. 11, 2018 (GB) 1800452.3

(51) Int. Cl. H01L 29/16; H01L 21/265; H01L 21/263; H01L 21/02

(52) U.S. Cl. CPC H01L 29/1606; H01L 21/02205; H01L 21/2636; H01L 21/26506

(57) ABSTRACT

A chemically-doped graphene transistor comprising a plurality of graphene layers and having a first doped region separated from a second doped region by a third doped region, wherein the first and second doped regions are of an opposite doping type to the third doped region, and wherein each of the first, second and third doped regions each comprise a separate electrical contact.

### REFERENCE TO RELATED APPLICATION

This application is a U.S. national stage application based on PCT/GB2019/050061, filed Jan. 10, 2019, claiming priority to Great Britain application no. 1800452.3, filed Jan. 11, 2018, the entire disclosures of which are incorporated herein by reference.

### FIELD OF THE INVENTION

The present invention relates to graphene transistors and to methods of making a graphene transistor. In particular, the invention provides an improved transistor based on carefully grown graphene layer structures.

### BACKGROUND

Graphene is a well-known material with a plethora of proposed applications driven by the material's theoretical extraordinary properties. Good examples of such properties and applications are detailed in ‘The Rise of Graphene’ by A. K. Geim and K. S. Novoselev, Nature Materials, vol. 6, March 2007, 183-191.

WO 2017/029470, the content of which is incorporated herein by reference, discloses methods for producing two-dimensional materials. Specifically, WO 2017/029470 discloses a method of producing two-dimensional materials such as graphene, comprising heating a substrate held within a reaction chamber to a temperature that is within a decomposition range of a precursor, and that allows graphene formation from a species released from the decomposed precursor; establishing a steep temperature gradient (preferably >1000° C. per meter) that extends away from the substrate surface towards an inlet for the precursor; and introducing precursor through the relatively cool inlet and across the temperature gradient towards the substrate surface. The method of WO 2017/029470 may be performed using vapour phase epitaxy (VPE) systems and metal-organic chemical vapour deposition (MOCVD) reactors.

The method of WO 2017/029470 provides two-dimensional materials with a number of advantageous characteristics including: very good crystal quality; large material grain size; minimal material defects; large sheet size; and are self-supporting. However, there remains a need for fast and low-cost processing methods for fabricating devices from the two-dimensional materials.

Transistors are well known in the art and a basic transistor structure is shown in FIG. 1. The device (1) is operated by applying a gate bias so that electron accumulation occurs in the intrinsic region (5). At sufficient gate bias, tunneling occurs when the conduction band of the intrinsic region (5) aligns with the valence band of the p-type region (10). Electrons from the valence band of the p-type region (10) tunnel into the conduction band of the intrinsic region (5) and current can flow across the device (1) to the n-type region (15). As the gate bias is reduced, the bands become misaligned and current can no longer flow. In this figure the intrinsic region is provided on a semiconductor wafer (20) and the device (1) is provided with three electrodes: the source (25), the gate electrode (30) sitting on a dielectric region (31) and the drain electrode (35).

The layers of an NPN transistor must have correct voltages connected across them. The voltage of the gate (G) must be more positive than that of the drain (D). The voltage of the source (S) must be more positive than that of the base. The drain supplies electrons. The gate pulls these electrons from the drain because it has a more positive voltage than the drain. This movement of electrons creates a flow of current through the transistor.

Examples of transistors comprising graphene are known in the art. For example, Graphene can be used as a tunneling transistor in an analogous way (G. Alymov, et. al., Scientific Reports 6, Article number: 24654 (2016)). In this case, intrinsic graphene is used, and positive and negative voltages are respectively applied to the two doping gates, to form a p-i-n structure, with the intrinsic graphene under the control gate acting as the i region. A back-gate voltage, VB, is applied to open a small bandgap. In this case, due to the tunneling operation of the device, it is actually beneficial to have a small bandgap. Nevertheless though, a bandgap is necessary in this example, as is a p-i-n structure.

An alternative approach is to use graphene without a bandgap, and to physically separate two areas of graphene from each other with a semiconductor or dielectric material. This is disclosed, for example, by D. A. Svintsov, et. al., “Tunnel Field Effect Transistors with Graphene Channels”, IX INTERNATIONAL CONFERENCE “SILICON 2012”, ST. PETERSBURG, Jul. 9-13, 2012. In this case, a graphene layer is physically split into two, and a back-gate voltage is applied. When this back gate voltage is increased, the density of states in the graphene sheet will increase, which will induce a tunnel current through the gap. Alternatively, if the dielectric/semiconductor gap is small enough, the application of a top gate bias will also enable tunneling. This configuration does not necessarily need a bandgap, and it does not need a pn junction or a p-i-n junction.

EP 3015426 discloses a graphene layer, a method of forming the graphene layer, a device including the graphene layer, and a method of manufacturing the device are provided. Specifically, this document teaches a CVD process using a metal catalyst to produce graphene.

US 2012/0241069 discloses direct synthesis of patterned graphene by deposition. Specifically, this document teaches the use of a metal catalyst surface to produce graphene.

US 2017/0175258 discloses facile route to template growth of two-dimensional layered materials. Specifically, this document relates to the growth of binary metal based two-dimensional materials rather than graphene.

WO 2013/028826 discloses methods for growing microstructured and nanostructured graphene by growing the microstructured and nanostructured graphene from the bottom-up directly in the desired pattern. Specifically, this document teaches the use of a copper catalyst surface to produce graphene.

Kim et al., “Chemical vapour deposition-assembled graphene field effect transistor on hexagonal boron nitride”, Applied Physics Letters, 2011, 98, 262103 relates to the electrical properties of monolayer graphene assembled by chemical-vapour-deposition (CVD) as impacted by supporting substrate material. Specifically, this document relates to the growth of graphene using CVD on a copper surface then removing the graphene from the copper via etching then manually placing the graphene on to boron nitride.

Perez-mas et al., “Graphene patterning by nanosecond laser ablation: the effect of the substrate interaction with graphene” Journal of Physics D: Applied Physics, 2016, 49, 305301 relates to the development of patterned graphene/substrate by means of green nanosecond pulse laser irradiation. Specifically, this document relates to CVD grown graphene on metal foil which is removed from the foil and then manually placed on silicon dioxide substrate.

Woong et al., “Atomic layer etching for full graphene device fabrication”, Carbon, 2012, 50, 429 relates to fabrication of full graphene devices. Specifically, this document relates to the growth of graphene on copper foil by CVD. However, the material produced does not appear to be graphene.

### SUMMARY OF THE INVENTION

It is an object of the present invention to provide an improved graphene transistor and method for producing a graphene transistor which overcomes, or substantially reduce, problems associated with the prior art or at least provide a commercially useful alternative thereto.

According to a first aspect there is provided a chemically-doped graphene transistor comprising a plurality of graphene layers and having a first doped region separated from a second doped region by a third doped region, wherein the first and second doped regions are of an opposite doping type to the third doped region, and wherein each of the first, second and third doped regions each comprise a separate electrical contact.

### BRIEF DESCRIPTION OF THE FIGURES

FIG. 1 shows a schematic of a transistor design.

FIG. 2 shows a schematic layer design of a transistor suitable in accordance with the disclosure.

FIG. 3 shows a schematic cross-section of a graphene-layer growth chamber for use in the method described herein.

### DETAILED DESCRIPTION OF THE INVENTION

The present disclosure will now be described further. In the following passages different aspects/embodiments of the disclosure are defined in more detail. Each

aspect/embodiment so defined may be combined with any other aspect/embodiment or aspects/embodiments unless clearly indicated to the contrary. In particular, any feature indicated as being preferred or advantageous may be combined with any other feature or features indicated as being preferred or advantageous.

The present invention relates to a graphene transistor. That is, a transistor which functions on the basis of a graphene layer structure. Examples of such devices are known, as described above. However, they do not have the structure described herein. Indeed, the inventors have discovered that it is possible to make a transistor having all of the electrical advantages of graphene in a straight-forward growth process as described below.

The graphene transistor comprises chemically-doped graphene comprising a plurality of graphene layers. The present disclosure uses the term graphene layer structure to refer to this arrangement of multiple layers of graphene. A preferred graphene layer structure has from 2 to 40 graphene layers, preferably 2 to 10. Graphene is a well-known term in the art and refers to an allotrope of carbon comprising a single layer of carbon atoms in a hexagonal lattice. The term graphene used herein encompasses structures comprising multiple graphene layers stacked on top of each other. The term graphene layer is used herein to refer to a graphene monolayer. Said graphene monolayers are doped for the formation of a transistor. The graphene layer structures disclosed herein are distinct from graphite since the layer structures retain graphene-like properties.

A general discussion of the growth of doped graphene layer structures is provided below. The chemically doped graphene layer structure has a first doped region separated from a second doped region by a third doped region, wherein the first and second doped regions are of an opposite doping type to the third doped region. The first, second and third regions of the transistor are formed of doped graphene. Accordingly, the first doped region is a first doped graphene region. That is, the first and second doped regions may be n-type doped or p-typed doped, while the third doped region will be p-type doped or n-type doped respectively. These regions function as the correspondingly described regions of the device discussed above. N-type and p-type doping of layers is known in the art and discussed in more detail below

In addition, each of the first, second and third doped regions each comprise a separate electrical contact. These represent the conventional source, gate and drain electrodes of a transistor design. These electrodes may be formed of any suitable material and may be applied by any conventional technique. For example, copper electrodes may be applied by sputtering.

Preferably the third doped region is in direct contact with the first and second doped regions. Indeed, as described in the method below, the regions may preferably be formed together in a single step with the doping changed after formation. In one embodiment, the three doped regions are all made as a single layer having the same doping, but the third region (or in a less preferred embodiment the first and second), is then counterion doped to achieve an opposite aggregate doping. Such counterion doping can be discerned by careful inspection of such a material.

Suitable dimensions for the transistor would be up to 1-2 cm for high power transistors, which have breakdown voltages of over 1000V; 1-10 mm scale for devices are used in high power applications, in addition to medium power applications. 1 to 100 μm scale devices are typically used for lower power and higher frequency applications; 1 to 100 nm scale devices are generally used in semiconductor fabrication with 10 nm class being prevalent in 2017, and 5 nm expected by 2020. In other words, the transistor may have a size of from 1 nm up to 2 cm, depending on the intended end application.

There are now described three methods for making a chemically-doped graphene transistor. These may be considered to cover: 1) an ion-implantation method; 2) a selective etching method; and 3) a selective masking method. These methods are preferably for producing the chemically-doped graphene transistor described above.

According to a second aspect there is described a method for the production of a chemically-doped graphene transistor, the method comprising:

providing a substrate on a heated susceptor in a reaction chamber, the chamber having a plurality of cooled inlets arranged so that, in use, the inlets are distributed across the substrate and have a constant separation from the substrate,

supplying a flow comprising a precursor compound through the inlets and into the reaction chamber to thereby decompose the precursor compound and form a plurality of graphene layers on the substrate,

wherein the inlets are cooled to less than 100° C., preferably 50 to 60° C., and the susceptor is heated to a temperature of at least 50° C. in excess of a decomposition temperature of the precursor,

wherein the flow comprising the precursor compound comprises a source of an N-type dopant or a source of P-type dopant; and

selectively counter-doping a portion of the graphene on the substrate with a dopant of an opposite type to the dopant present in the flow comprising the precursor compound.

This aspect is referred to herein as the ion-implantation method.

The method comprises a first step of providing a substrate on a heated susceptor in a reaction chamber. The substrate of the present method may be any known MOCVD or VPE substrate. It is preferred that the substrate provides a crystalline surface upon which the graphene is produced as ordered crystal lattice sites provide a regular array of nucleation sites that promote the formation of good graphene crystal overgrowth. The most preferred substrates provide a high density of nucleation sites. The regular repeatable crystal lattice of substrates used for semiconductor deposition is ideal, the atomic stepped surface offering diffusion barriers. Examples of suitable substrates include silicon, nitride semiconductor materials (AlN, AlGaN, GaN, InGaN and complexes thereof), arsenide/phosphide semiconductors (GaAs, InP, AlInP and complexes of), and diamond. Sapphire is particularly preferred.

MOCVD is a term used to describe a system used for a particular method for the deposition of layers on a substrate. While the acronym stands for metal-organic chemical vapour deposition, MOCVD is a term in the art and would be understood to relate to the general process and the apparatus used therefor and would not necessarily be considered to be restricted to the use of metal-organic reactants or to the production of metal-organic materials. Instead, the use of this term indicates to the person skilled in the art a general set of process and apparatus features. MOCVD is further distinct from CVD techniques by virtue of the system complexity and accuracy. While CVD techniques allow reactions to be performed with straight-forward stoichiometry and structures, MOCVD allows the production of difficult stoichiometries and structures. An MOCVD system is distinct from a CVD system by virtue of at least the gas distribution systems, heating and temperature control systems and chemical control systems. An MOCVD system typically costs at least 10 times as much as a typical CVD system. CVD techniques cannot be used to achieve high quality graphene layer structures.

MOCVD can also be readily distinguished from atomic layer deposition (ALD) techniques. ALD relies on step-wise reactions of reagents with intervening flushing steps used to remove undesirable byproducts and/or excess reagents. It does not rely on decomposition or dissociation of the reagent in the gaseous phase. It is particularly unsuitable for the use of reagents with low vapour pressures such as silanes, which would take undue time to remove from the reaction chamber.

Generally it is preferred to have a substrate that is as thin as possible to ensure thermal uniformity across the substrate during graphene production. Suitable thicknesses are 50 to 300 microns, preferably 100 to 200 microns and more preferably about 150 microns. The minimum thickness of the substrate is however determined in part by the substrate's mechanical properties and the maximum temperature at which the substrate is to be heated. The maximum area of the substrate is dictated by the size of the close coupled reaction chamber. Preferably the substrate has a diameter of at least 2 inches, preferably 2 to 24 inches and more preferably 6 to 12 inches. This substrate can be cut after growth to form individual devices using any known method.

The substrate is provided on a heated susceptor in a reaction chamber as described herein. Reactors suitable for use in the present method are well known and include heated susceptor capable of heating the substrate to the necessary temperatures. The susceptor may comprise a resistive heating element or other means for heating the substrate.

The chamber has a plurality of cooled inlets arranged so that, in use, the inlets are distributed across the substrate and have a constant separation from the substrate. The flow comprising a precursor compound may be provided as a horizontal laminar flow or may be provided substantially vertically. Inlets suitable for such reactors are well known and include Planetary and Showerhead reactors available from Aixtron.

The spacing between the substrate surface upon which the graphene is formed and the wall of the reactor directly above the substrate surface has a significant effect on the reactor thermal gradient. It is preferred that the thermal gradient is as steep as possible which correlates to a preferred spacing that is as small as possible. A smaller spacing changes the boundary layer conditions at the substrate surface that in turn promotes uniformity of graphene layer formation. A smaller spacing is also highly preferred as it allows refined levels of control of the process variables, for example reduced precursor consumption through lower input flux, lower reactor and hence substrate temperature which decreases stresses and non-uniformities in the substrate leading to more uniform graphene production on the substrate surface and hence, in most cases, significantly reduced process time.

Experimentation suggests a maximum spacing of about 100 mm is suitable. However, ore reliable and better quality two-dimensional crystalline material is produced using a much smaller spacing equal to or less than about 20 mm, such as 1 to 5 mm; a spacing equal or less than about 10 mm promotes the formation of stronger thermal currents proximate the substrate surface that increase production efficiency.

Where a precursor is used that has a relative low decomposition temperature such that there is likely to be a more than negligible degree of decomposition of the precursor at the temperature of the precursor inlet, a spacing below 10 mm is strongly preferred to minimise the time taken for the precursor to reach the substrate.

During the production method, a flow is supplied comprising a precursor compound through the inlets and into the reaction chamber to thereby decompose the precursor compound and form graphene on the substrate. The flow comprising a precursor compound may further comprise a dilution gas. Suitable dilution gases are discussed in more detail below.

Preferably the precursor compound is a hydrocarbon. Preferably a hydrocarbon which is a liquid at room temperature and most preferably a C₅ to C₁₀ alkane. The use of simple hydrocarbons is preferred since this gives a pure source of carbon with gaseous hydrogen as a by-product. In addition, since the hydrocarbons are liquid at room temperature, they can be obtained in a highly pure liquid form at low cost. Preferably the precursor compound include hexane.

The precursor is preferably in the gas phase when passed over the heated substrate. There are two variables to be considered: pressure within the close coupled reaction chamber and the gas flow rate into the chamber.

The preferred pressure selected depends upon the precursor chosen. In general terms, where precursors of greater molecular complexity are used, improved two-dimensional crystalline material quality and rate of production is observed using lower pressures, e.g. less than 500 m bar. Theoretically, the lower the pressure the better, but the benefit provided by very low pressures (e.g. less than 200 mbar) will be offset by very slow graphene formation rates.

Conversely for less complex molecular precursors, higher pressures are preferred. For example where methane is used as a precursor for graphene production, a pressure of 600 mbar or greater may be suitable. Typically, it is not expected to use pressures greater than atmospheric because of its detrimental impact on substrate surface kinetics and the mechanical stresses placed on the system. A suitable pressure can be selected for any precursor through simple empirical experimentation, which may involve for example, five test runs using respective pressures of 50 mbar, 950 m bar and three others of equidistance intervals between the first two. Further runs to narrow the most suitable range can then be conducted at pressures within the interval identified in the first runs as being most suitable. The preferred pressure for hexane is from 50 to 800 m bar.

The precursor flow rate can be used to control the graphene deposition rate. The flow rate chosen will depend upon the amount of the species within the precursor and the area of the layer to be produced. Precursor gas flow rate needs to be high enough to allow coherent graphene layer formation on the substrate surface. If the flow is above an upper threshold rate, bulk material formation, e.g. graphite, will generally result or increased gas phase reactions will occur resulting in solid particulates suspended in the gas phase that are detrimental to graphene formation and/or may contaminate the graphene layer. The minimum threshold flow rate can be theoretically calculated using techniques known to the person skilled in the art, by assessing the amount of the species required to be supplied to the substrate to ensure sufficient atomic concentrations are available at the substrate surface for a layer to form. Between the minimum and upper threshold rates, for a given pressure and temperature, flow rate and graphene layer growth rate are linearly related.

Preferably a mixture of the precursor with a dilution gas is passed over the heated substrate within a close coupled reaction chamber. The use of a dilution gas allows further refinement of the control of the carbon supply rate.

It is preferred that the dilution gas includes one or more of hydrogen, nitrogen, argon and helium. These gases are selected because they will not readily react with a large number of available precursors under typical reactor conditions, nor be included in the graphene layer. Notwithstanding, hydrogen may react with certain precursors. Additionally, nitrogen can be incorporated into the graphene layer under certain conditions. In such instances one of the other dilution gases can be used.

In spite of these potential problems, hydrogen and nitrogen are particularly preferred because they are standard gases used in MOCVD and VPE systems.

The susceptor is heated to a temperature of at least 50° C. in excess of a decomposition temperature of the precursor, more preferably from 100 to 200° C. in excess. The preferred temperature to which the substrate is heated is dependent upon the precursor selected. The temperature selected needs to be high enough to allow at least partial decomposition of the precursor in order to release the species, but preferably not so high as to promote increased recombination rates in the gas phase away from the substrate surface and hence production of unwanted by-products. The selected temperature is higher than the complete decomposition temperature to promote improved substrate surface kinetics and so encourage formation of graphene with good crystal quality. For hexane, the most preferred temperature is about 1200° C., such as from 1150 to 1250° C.

In order for there to be a thermal gradient between the substrate surface and the introduction point for precursor, the inlet will need to be of a lower temperature than the substrate. For a fixed separation a greater temperature difference will provide a steeper temperature gradient. As such it is preferred that at least the wall of the chamber through which the precursor is introduced, and more preferably the walls of the chamber are cooled. Cooling may be achieved using a cooling system, for example, using fluid, preferably liquid, most preferably water, cooling. The reactor's walls may be maintained at constant temperature by water cooling. The cooling fluid may flow around the inlet(s) to ensure that the temperature of the inner surface of the reactor wall through which the inlets extend, and thus of the precursor itself as it passes through the inlet and into the reaction chamber, is substantially lower than the substrate temperature. The inlets are cooled to less than 100° C., preferably 50 to 60° C.

It is necessary to dope the graphene. This may be achieved by introducing a doping element into the close coupled reaction chamber and selecting a temperature of the substrate, a pressure of the reaction chamber and a gas flow rate to produce a doped graphene. Straightforward empirical experimentation can be used to determine these variables using the guidance described above. This process can be used with or without a dilution gas. There is no perceived restriction as to doping element that may be introduced. Commonly used dopant elements for the production of graphene include silicon, magnesium, zinc, arsenic, oxygen, boron, bromine and nitrogen. These may be included in addition to the precursor compound, or as part of the precursor compound (such as the use of an amine to provide nitrogen).

n-type doping of graphene can be achieved using any element that will contribute additional electrons to the structure. Such elements include Nitrogen, Bromine and Phosphorous amongst many others. Preferred methods for achieving n-type doping include using a nitrogen-containing precursor introducing nitrogen into the graphene lattice, or a nitrogen containing carrier gas which can be decomposed in the reactor and introduce nitrogen into the lattice. This has been largely due to the easily available precursors and gases.

p-type doping of graphene can be achieved using any element that will contribute additional holes to the structure. Such elements include Magnesium, Boron and Oxygen, amongst many others. Preferred methods for achieving p-type doping include using a magnesium or boron containing precursors to introduce magnesium and boron into the graphene lattice. Again, this has been largely due to the readily available precursors.

In the above-mentioned cases, the doping element has been introduced through the carbon containing precursor at the same time as providing carbon for the graphene growth. For example, the use of Magnesocene can provide carbon from decomposition of the cyclopentadienyl ring at the same time as providing magnesium from the metal-organic bond dissociation. Similarly, boron doping can be provided by Triethyl or Trimethylboron where the CH₃ radical provides carbon, and the bromine delivered through the metal-radical dissociation.

Preferred levels of doping are in the range of from 10¹⁰ atoms/cm³ to 10¹⁹ atoms/cm³. This can be measured by van der Pauw Hall measurements, capacitance-voltage profiling.

Preferably the counter-doping is performed by diffusion, ion-implantation, alloy doping, vapour phase epitaxy magnetic doping, neutron transmutation doping, or modulation doping, preferably wherein the counter-doping is performed by ion-implantation. Diffusion includes diffusion in the gas phase, diffusion in liquid phase, diffusion with a solid source, and all of these methods can be carried out at high or low temperatures and high or low pressures. Such doping techniques are well known in the broader field of semiconductors, but not necessarily in combination with graphene layer structures.

Preferred levels of counter-ion doping are in the range of from 10¹² atoms/cm³ to 10²¹ atoms/cm³. As will be appreciated, the level of counter-ion doping is required to change the over-all doping of the layer from one type to the other. Thus the final apparent doping of the counter-doped layer is preferably at least 10¹⁰ atoms/cm³ to 10¹⁹ atoms/cm³. This can be measured by van der Pauw Hall measurements, capacitance-voltage profiling.

According to a further aspect there is provided a method for the production of a chemically-doped graphene transistor, the method comprising:

providing a substrate on a heated susceptor in a reaction chamber, the chamber having a plurality of cooled inlets arranged so that, in use, the inlets are distributed across the substrate and have a constant separation from the substrate,

supplying a first flow comprising a precursor compound through the inlets and into the reaction chamber to thereby decompose the precursor compound and form a plurality of graphene layers on the substrate,

wherein the inlets are cooled to less than 100° C., preferably 50 to 60° C., and the susceptor is heated to a temperature of at least 50° C. in excess of a decomposition temperature of the precursor, and wherein the flow comprising the precursor compound comprises a source of an N-type dopant or a source of P-type dopant; and

selectively removing one or more portions of the graphene, and selectively growing one or more replacement portions using a second flow comprising a precursor compound and comprising a dopant of an opposite type to the dopant present in the first flow.

All of the method aspects described above for the ion-implantation method can be applied equally to this further aspect. That is, the selection of materials and process properties as discussed in respect of the ion-implantation method general apply also to this further aspect. For example the choice substrate, precursor and dopant materials apply also to this aspect and the selection of process temperatures, separation distances, flow rates and pressures also apply to this second aspect.

Preferably the step of selectively removing one or more portions of the graphene comprises ablating the one or more portions of the graphene with a laser or chemically etching the one or more portions of the graphene. Chemical etching methods are well known in the art.

When using a laser to selectively ablate graphene from the substrate, suitable lasers are those having wavelength in excess of 600 nm and a power of less than 50 Watts. Preferably the laser has a wavelength of from 700 to 1500 nm. Preferably the laser has a power of from 1 to 20 Watts. This allows the graphene to be readily removed without damaging the neighbouring graphene or the substrate.

Preferably the laser spot size is kept as small as possible (i.e. have a better resolution). For example, the present inventors have worked at a spot size of 25 microns. Focus should be as precise as possible. It has also been found that it is better to pulse the laser as opposed to continuous lasing, in order to prevent substrate damage.

According to a further aspect there is provided a method for the production of a chemically-doped graphene transistor, the method comprising:

providing a substrate on a heated susceptor in a reaction chamber, the chamber having a plurality of cooled inlets arranged so that, in use, the inlets are distributed across the substrate and have a constant separation from the substrate,

introducing a first mask between the substrate and the inlets to provide first masked and first unmasked portions of the substrate,

supplying a first flow comprising a first precursor compound through the inlets and into the reaction chamber to thereby decompose the precursor compound and form a plurality of graphene layers on the first unmasked portions of the substrate,

introducing a second mask between the substrate and the inlets to provide second masked and second unmasked portions of the substrate,

supplying a second flow comprising a second precursor compound through the inlets and into the reaction chamber to thereby decompose the precursor compound and form a plurality of graphene layers on the second unmasked portions of the substrate,

wherein the inlets are cooled to less than 100° C., preferably 50 to 60° C., and the susceptor is heated to a temperature of at least 50° C. in excess of a decomposition temperature of the first or second precursor, and

wherein the first flow comprising the first precursor compound comprises a source of an N-type dopant or a source of P-type dopant; and the second flow comprising the second precursor compound comprises a dopant of an opposite type to the dopant present in the first flow.

All of the method aspects described above for the ion-implantation method and the selective etching method can be applied equally to this further aspect. That is, the selection of materials and process properties as discussed in respect of the ion-implantation method apply also to this further aspect. For example the choice substrate, precursor and dopant materials apply also to this aspect and the selection of process temperatures, separation distances, flow rates and pressures also apply to this second aspect.

Preferably the first and second precursor compounds are different.

Preferably the first masked portion corresponds to the second unmasked portion and the second masked portion corresponds to the first unmasked portion. The use of masks in semiconductor device growth and especially using MOCVD are well known in the art.

Elements of the above-described methods will now be discussed in more detail.

A close coupled reaction chamber provides a separation between the substrate surface upon which the graphene is formed and the entry point at which the precursor enters the close coupled reaction chamber that is sufficiently small that the fraction of precursor that reacts in the gas phase within the close coupled reaction chamber is low enough to allow the formation of graphene. The upper limit of the separation may vary depending upon the precursor chosen, substrate temperate and pressure within the close coupled reaction chamber.

Compared with the chamber of a standard CVD system, the use of a close coupled reaction chamber, which provides the aforementioned separation distance, allows a high degree of control over the supply of the precursor to the substrate; the small distance provided between the substrate surface on which the graphene is formed and the inlet through which the precursor enters the close coupled reaction chamber, allows for a steep thermal gradient thereby providing a high degree of control over the decomposition of the precursor.

The relatively small separation between the substrate surface and the chamber wall provided by a close coupled reaction chamber, compared with the relatively large separation provided by a standard CVD system allows:

1) a steep thermal gradient between the precursor's entry point and the substrate surface;

2) a short flow path between the precursor entry point and the substrate surface; and

3) a close proximity of the precursor entry point and the point of graphene formation.

These benefits enhance the effects that deposition parameters including substrate surface temperature, chamber pressure and precursor flux have on the degree of control over the delivery rate of the precursor to the substrate surface and the flow dynamics across the substrate surface.

These benefits and the greater control provided by these benefits enable minimisation of gas phase reactions within the chamber, which are detrimental graphene deposition; allow a high degree of flexibility in the precursor decomposition rate, enabling efficient delivery of the species to the substrate surface; and gives control over the atomic configuration at the substrate surface which is impossible with standard CVD techniques

Through both simultaneously heating the substrate and providing cooling to the wall of the reactor directly opposite the substrate surface at the inlet, a steep thermal gradient can be formed whereby the temperature is a maximum at the substrate surface and drops rapidly towards the inlet. This ensures the reactor volume above the substrate surface has a significantly lower temperature than the substrate surface itself, largely reducing the probability of precursor reaction, in the gas phase, until the precursor is proximate the substrate surface.

An alternative design of MOCVD reactor is also contemplated which has been demonstrated to be efficient for graphene growth as described herein. This alternative design is a so-called High Rotation Rate (HRR) or “Vortex” flow system. Whereas the close-coupled reactor described above focussed on creating graphene using a very high thermal gradient, the new reactor has a significantly wider spacing between the injection point and growth surface or substrate. Close coupling allowed extremely rapid dissociation of precursors delivering elemental carbon, and potentially other doping elements, to the substrate surface allowing the formation of graphene layers. In contrast, the new design relies on a vortex of the precursors.

In the new reactor design, in order to promote laminar flow over the surface this system utilizes a higher rotation rate to impinge a high level of centrifugal acceleration on the injected gas stream. This results in a vortex type fluid flow within the chamber. The effect of this flow pattern is a significantly higher residency time of the precursor molecules proximate to the growth/substrate surface compared to other reactor types. For the deposition of graphene this increased time is what promotes the formation of elemental layers.

However, this type of reactor does have a couple of parasitic issues, firstly the amount of precursor required to achieve the same amount of growth as other reactors increases due to the reduced mean free path that this flow regime causes, resulting in more collisions of precursor molecules delivering non-graphene growth atomic recombination. However, the use of reagents such as hexane which are relatively cheap means that this problem can be readily overcome. Additionally, the centrifugal motion has varying impacts on atoms and molecules of different sizes resulting in the ejection of different elements at different velocities. While this probably assists graphene growth due to the uniform rate of carbon supply with ejection of unwanted precursor by-products it can be detrimental to desired effects such as elemental doping.

An example of such a reaction system is the Veeco Instruments Inc. Turbodisc technology, K455i or Propel tools.

Preferably the reactor used herein in a high rotation rate reactor. This alternative design of reactor may be characterised by its increased spacing and high rotation rate. Preferred spacings are from 50 to 120 mm, more preferably 70 to 100 mm. The rotation rate is preferably from 100 rpm to 3000 rpm, preferably 1000 rpm to 1500 rpm.

In FIG. 2, the device 200 is made by first depositing n-type graphene 210 on the substrate 205 (sapphire etc.), or on a semiconductor layer 215 formed on the substrate (AlN etc.). Metal contacts 220 are then deposited onto the n-type graphene through a mask. Next, a p-type region 225 is created, by ion implantation, diffusion, etc. by introducing a p-dopant into the graphene layer at the location of a mask. Finally, a dielectric layer 230 such as Al₂O₃, ZnO₂, BN, SiO₂ or SiN is deposited on top of the p-type region and then a final metal contact 221 thereon completes the transistor structure.

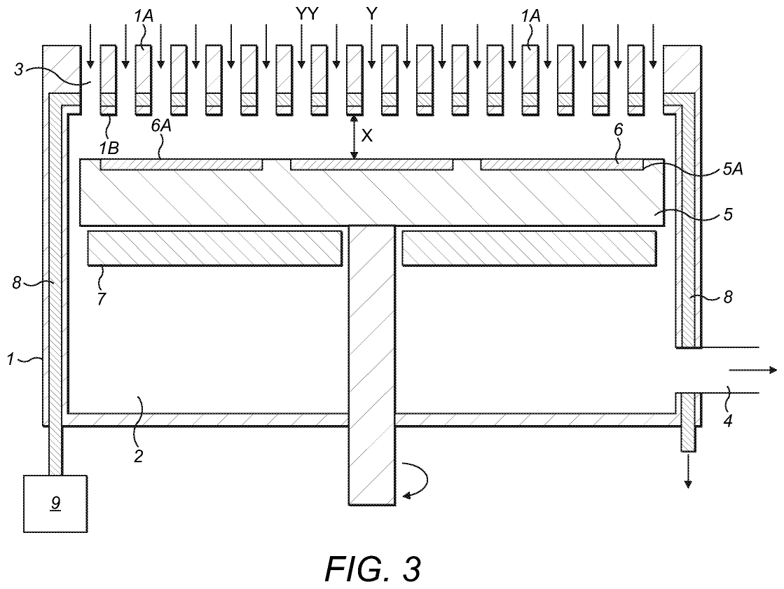

The reactor of FIG. 3 is constructed for the deposition of a graphene layer on a substrate through the method of Vapour Phase Epitaxy (VPE), in which a precursor is introduced to thermally, chemically and physically interact in the vicinity of and on the substrate to form a graphene layer structure having from 2 to 40, preferably 2 to 10 graphene layers.

The apparatus comprises a close coupled reactor 1 having a chamber 2 having an inlet or inlets 3 provided through a wall 1A and at least one exhaust 4. A susceptor 5 is arranged to reside within the chamber 2. The susceptor 5 comprises one or more recesses 5A for retaining one or more substrates 6. The apparatus further comprises means to rotate the susceptor 5 within the chamber 2; and a heater 7, e.g. comprising a resistive heating element, or RF induction coil, coupled to the susceptor 5 to heat the substrate 6. The heater 7 may comprise a single or multiple elements as required to achieve good thermal uniformity of the substrate 6. One or more sensors (not shown) within the chamber 2 are used, in conjunction with a controller (not shown) to control the temperature of the substrate 6.

The temperature of the walls of the reactor 1 is maintained at substantially constant temperature by water cooling.

The reactor walls define one or more internal channels and/or a plenum 8 that extend substantially adjacent (typically a couple of millimetres away) the inner surface of reactor walls including inner surface IB of wall 1A. During operation, water is pumped by a pump 9 through the channels/plenum 8 to maintain the inside surface 1B of wall 1A at or below 200° C. In part because of the relatively narrow diameter of the inlets 3, the temperature of the precursor (which is typically stored at a temperature much below the temperature of inside surface 1B), as it passes through inlets 3 through wall 1A into the chamber 1 will be substantially the same or lower than the temperature of the inside surface 1B of wall 1A.

The inlets 3 are arranged in an array over an area that is substantially equal or greater than the area of the one or more substrates 6 to provide substantially uniform volumetric flow over substantially the entirety of surfaces 6A of the one or more substrates 6 that face the inlets 3.

The pressure within the chamber 2 is controlled through control of precursor gas flows through inlet(s) 3 and exhaust gas through exhaust 4. Via this methodology, the velocity of the gas in the chamber 2 and across the substrate surface 6A and further the mean free path of molecules from the inlet 3 to substrate surface 6A are controlled. Where a dilution gas is used, control of this may also be used to control pressure through inlet(s) 3. The precursor gas is preferably hexane with a dopant such as nitrogen as the dilution gas.

The susceptor 5 is comprised from a material resistant to the temperatures required for deposition, the precursors and dilution gases. The susceptor 5 is usually constructed of uniformly thermally conducting materials ensuring substrates 6 are heated uniformly. Examples of suitable susceptor material include graphite, silicon carbide or a combination of the two.

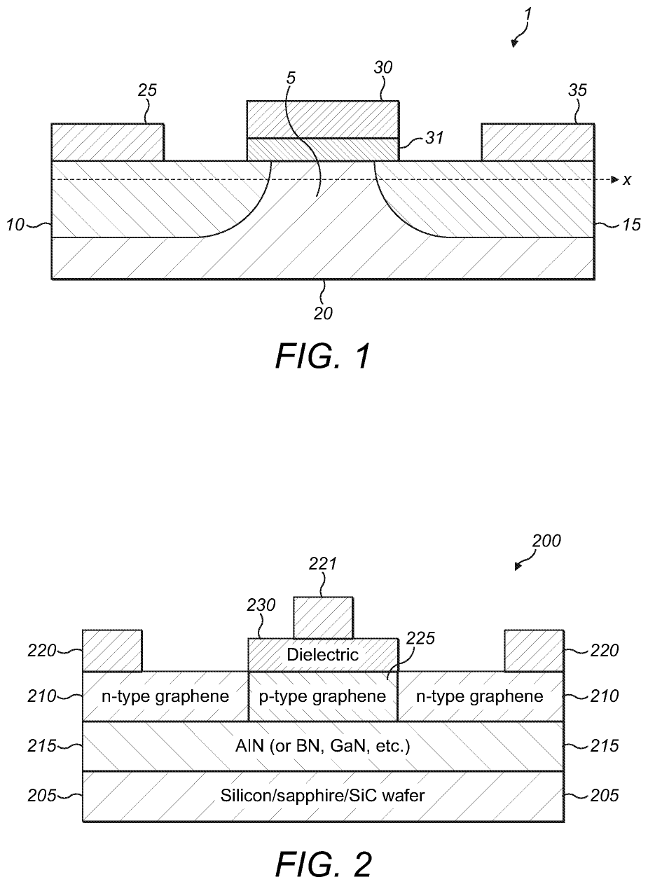

The substrate(s) 6 are supported by the susceptor 5 within the chamber 2 such that they face wall 1A with a separation, denoted in FIG. 1 by X, of between 1 mm-100 mm, though, as discussed above, generally the smaller the better. Where the inlets 3 protrude into or otherwise sit within the chamber 2, the relevant separation is measured between the substrate(s) 6 and exit of the inlets 3.

The spacing between the substrate 6 and the inlets 3 may be varied by moving the susceptor 5, substrate 6 & heater 7.

An example of a suitable close coupled reactor is the AIXTRON® CRIUS MOCVD reactor, or AIXTRON® R&D CCS system.

Precursors in gaseous form or in molecular form suspended in a gas stream are introduced (represented by arrows Y) into the chamber 2 through inlets 3 such that they will impinge on or flow over the substrate surface 6A. Precursors that may react with one another are kept separated until entering the chamber 2 by introduction through different inlets 3. The precursor or gas flux/flow rate is controlled externally to the chamber 2 via a flow controller (not shown), such as a gas mass flow controller.

A dilution gas may be introduced through an inlet or inlets 3 to modify gas dynamics, molecular concentration and flow velocity in the chamber 2. The dilution gas is usually selected with respect to the process or substrate 6 material such that it will not have an impact on the growth process of the graphene layer structure. Common dilution gases include Nitrogen, Hydrogen, Argon and to a lesser extent Helium.

After the graphene layer structure having from 2 to 40, preferably 2 to 10 graphene layers has been formed, the reactor is then allowed to cool and the substrate 6 is retrieved having a graphene layer structure thereon. Counterion doping is then achieved using ion-implantation to form the third region between two identically doped regions. Electrodes are then formed on each of the three regions by sputtering of copper. The transistors are then cut from the substrate using a conventional cutting technique.

### Examples

The present invention will now be described further with reference to the following non-limiting examples.

A preferred structure is shown in FIG. 2, albeit without the electrical contacts shown. In this case, the graphene oxide layer acts as a top gate dielectric. The silicon (or conductive SiC, etc.) wafer acts as a back-gate through a dielectric layer of AlN/BN/GaN/AlGaN or the like.

While the graphene is n-type, it will only be weakly n-type to ideally less than e12 cm⁻² carriers. By creating heavily doped n and p regions (through eg. ion implantation), it is possible to form a p-i-n structure, similar to FIG. 1. A back gate would not necessarily be necessary here, but it does rely on the graphene having a bandgap. This is best achieved by using a graphene multilayer.

The reactor was heated to a temperature of 950 degrees Celsius and pumped to 50 mbar in 20000 sccm of hydrogen carrier gas. 20 nm of AlN was grown using NH₃ and TMAI as precursors. The flow rate of NH₃ was 20 sccm and the flow rate of TMAI was 30 sccm where the precursor was held at 1300 mbar and 20 degrees Celsius. Next, the reactor was heated to 1200 degrees Celsius and a further 180 nm of AlN was grown.

The NH₃ and TMAI flows to the reactor were then turned off and the carrier gas was changed to nitrogen. Subsequently, the total carrier gas flow was set to 16000 sccm and bromomethane was flowed to the reactor for 9 minutes at a flow rate of 80 sccm where the bromomethane precursor was held at 1100 mbar and 25 degrees Celsius. 9 minutes of growth at these conditions led to graphene formation which was 5 layers thick, and doped with both nitrogen and bromine to make the graphene n-type. Finally the bromomethane was turned off and the reactor was cooled to room temperature in 10 minutes.

The wafer was processed such that metal Ohmic contacts were deposited by thermal evaporation through a mask to form a spacing of 50 um between the metal contacts. The contacts consisted of 20 nm of titanium followed by 100 nm of gold. Next, Al₂O₃ was deposited by atomic layer deposition in an area in between the two Ohmic contacts to a thickness of 30 nm. Prior to deposition however, the graphene was pretreated with water vapour in the atomic layer deposition reactor in order to dope the graphene with oxygen and turn it to p-type under the Al₂O₃ layer. Finally, a Schottky contact was deposited on top of the Al₂O₃ to act as the gate contact.

All percentages herein are by weight unless otherwise stated.

The foregoing detailed description has been provided by way of explanation and illustration, and is not intended to limit the scope of the appended claims. Many variations in the presently preferred embodiments illustrated herein will be apparent to one of ordinary skill in the art, and remain within the scope of the appended claims and their equivalents.

1. A chemically-doped graphene transistor comprising a plurality of graphene layers and having a first doped region separated from a second doped region by a third doped region, wherein the first and second doped regions are of an opposite doping type to the third doped region, and wherein each of the first, second and third doped regions each comprise a separate electrical contact.

2. The chemically-doped graphene transistor according to claim 1, wherein the third doped region is in direct contact with the first and second doped regions.

3. A method for the production of a chemically-doped graphene transistor, the method comprising:
providing a substrate on a heated susceptor in a reaction chamber, the chamber having a plurality of cooled inlets arranged so that, in use, the inlets are distributed across the substrate and have a constant separation from the substrate,
supplying a flow comprising a precursor compound through the inlets and into the reaction chamber to thereby decompose the precursor compound and form a plurality of graphene layers on the substrate,
wherein the inlets are cooled to less than 100° C., and the susceptor is heated to a temperature of at least 50° C. in excess of a decomposition temperature of the precursor,
wherein the flow comprising the precursor compound comprises a source of an N-type dopant or a source of P-type dopant; and
selectively counter-doping a portion of the graphene on the substrate with a dopant of an opposite type to the dopant present in the flow comprising the precursor compound.

4. The method according to claim 3, wherein the counter-doping is performed by diffusion, ion-implantation, alloy doping, vapour phase epitaxy magnetic doping, neutron transmutation doping, or modulation doping, preferably wherein the counter-doping is performed by ion-implantation.

5. A method for the production of a chemically-doped graphene transistor, the method comprising:
providing a substrate on a heated susceptor in a reaction chamber, the chamber having a plurality of cooled inlets arranged so that, in use, the inlets are distributed across the substrate and have a constant separation from the substrate,
supplying a first flow comprising a precursor compound through the inlets and into the reaction chamber to thereby decompose the precursor compound and form a plurality of graphene layers on the substrate,
wherein the inlets are cooled to less than 100° C., and the susceptor is heated to a temperature of at least 50° C. in excess of a decomposition temperature of the precursor, and wherein the flow comprising the precursor compound comprises a source of an N-type dopant or a source of P-type dopant; and
selectively removing one or more portions of the graphene, and selectively growing one or more replacement portions using a second flow comprising a precursor compound and comprising a dopant of an opposite type to the dopant present in the first flow.

6. The method according to claim 5, wherein the step of selectively removing one or more portions of the graphene comprises ablating the one or more portions of the graphene with a laser or chemically etching the one or more portions of the graphene.

7. A method for the production of a chemically-doped graphene transistor, the method comprising:
providing a substrate on a heated susceptor in a reaction chamber, the chamber having a plurality of cooled inlets arranged so that, in use, the inlets are distributed across the substrate and have a constant separation from the substrate,
introducing a first mask between the substrate and the inlets to provide first masked and first unmasked portions of the substrate,
supplying a first flow comprising a first precursor compound through the inlets and into the reaction chamber to thereby decompose the precursor compound and form a plurality of graphene layers on the first unmasked portions of the substrate,
introducing a second mask between the substrate and the inlets to provide second masked and second unmasked portions of the substrate,
supplying a second flow comprising a second precursor compound through the inlets and into the reaction chamber to thereby decompose the precursor compound and form a plurality of graphene layers on the second unmasked portions of the substrate,
wherein the inlets are cooled to less than 100° C., and the susceptor is heated to a temperature of at least 50° C. in excess of a decomposition temperature of the first or second precursor, and
wherein the first flow comprising the first precursor compound comprises a source of an N-type dopant or a source of P-type dopant; and the second flow comprising the second precursor compound comprises a dopant of an opposite type to the dopant present in the first flow.

8. The method according to claim 7, wherein the first and second precursor compounds are different.

9. The method according to claim 7, wherein the first masked portion corresponds to the second unmasked portion and the second masked portion corresponds to the first unmasked portion.

10. The method according to claim 3, wherein the N-type doping is provided by:
(i) the inclusion of nitrogen gas in a flow comprising precursor compound;
(ii) the use of a nitrogen-containing precursor compound; and/or
wherein the P-type doping is provided the use of a magnesium- or bromine-containing precursor compound.

11. The method according to claim 3, wherein the chemically-doped graphene transistor comprises a plurality of graphene layers and having a first doped region separated from a second doped region by a third doped region, wherein the first and second doped regions are of an opposite doping type to the third doped region, and wherein each of the first, second and third doped regions each comprise a separate electrical contact.

12. (canceled)

13. The method according to claim 5, wherein the N-type doping is provided by:
(i) the inclusion of nitrogen gas in a flow comprising precursor compound;
(ii) the use of a nitrogen-containing precursor compound; and/or
wherein the P-type doping is provided the use of a magnesium- or bromine-containing precursor compound.

14. The method according to claim 7, wherein the N-type doping is provided by:
(i) the inclusion of nitrogen gas in a flow comprising precursor compound;
(ii) the use of a nitrogen-containing precursor compound; and/or
wherein the P-type doping is provided the use of a magnesium- or bromine-containing precursor compound.

15. The method according to claim 5 wherein the chemically-doped graphene transistor comprises a plurality of graphene layers and having a first doped region separated from a second doped region by a third doped region, wherein the first and second doped regions are of an opposite doping type to the third doped region, and wherein each of the first, second and third doped regions each comprise a separate electrical contact.

16. The method according to claim 7 wherein the chemically-doped graphene transistor comprises a plurality of graphene layers and having a first doped region separated from a second doped region by a third doped region, wherein the first and second doped regions are of an opposite doping type to the third doped region, and wherein each of the first, second and third doped regions each comprise a separate electrical contact.
